(19) United States
(12) Patent Application Publication
(10) Pub. No.: US 2026/0113834 A1
(43) Pub. Date: Apr. 23, 2026

(54) Electronic Device and System With an Improved Cooling Concept

(71) Applicant: Bayerische Motoren Werke Aktiengesellschaft, Muenchen (DE)

(72) Inventors: Herbert BLENDL, Hohenthann (DE); Daniel WEIDA, Muenchen (DE)

(21) Appl. No.: 18/703,880

(22) PCT Filed: Oct. 28, 2022
(86) PCT No.: PCT/EP2022/080248

§ 371 Date: Apr. 23, 2024

(30) Foreign Application Priority Data
Nov. 15, 2021 (DE) 10 2021 129 642.0

(51) Int. Cl. H05K 1/02; H05K 1/181; H05K 1/184

(52) U.S. Cl. CPC H05K 1/0204; H05K 1/0209; H05K 1/0233; H05K 1/181; H05K 1/184; H05K 2201/066; H05K 2201/09063; H05K 2203/044

(57) ABSTRACT

An electronic device including at least one printed circuit board and at least one electrical or electronic component. The printed circuit board has an assembly side and an opposite soldering side and includes at least one clearance opening, which corresponds to the at least one component and passes through the printed circuit board in the direction of its thickness. The at least one component adjoins the clearance opening and protrudes into it, and therefore the component is exposed from the soldering side and can be cooled by means of a cooling device facing the soldering side.

### BACKGROUND AND SUMMARY

The present invention relates to an electronic device and a system comprising an electronic device and a cooling device.

Printed circuit boards are used to provide complex electronic devices with multiple subcomponents (hereinafter: components). The components are arranged here on the printed circuit board starting from the assembly side of the printed circuit board and subsequently fixed, for example, by surface-mounting technology (SMT) or through-hole technology (THT) mounting methods.

At least some of the applied components induce significant amounts of heat during operation, which can negatively influence the functionality of the components or the entire electronic device. In order to ensure the functionality of the components and the electronic device, a cooling device therefore has to be provided, which is configured to transport the occurring amounts of heat away. The cooling then has to take place from the direction of the assembly side of the printed circuit board. Moreover, different components often have sometimes greatly differing dimensions.

On the one hand, multiple individual cooling devices can then be provided, which are each configured to cool a specific component of the electronic device. However, such an arrangement has many individual parts and therefore a high level of complexity.

On the other hand, a single cooling device can also be provided, which is configured to cool multiple components of the electronic device. However, due to the varying dimensions of the individual components, the cooling device then has to be structured in order to take into consideration the different dimensions of the components, for example different height dimensions perpendicular to the surface of the assembly side of the printed circuit board. A complexly structured cooling device is thus necessary, which requires a high level of production expenditure. Moreover, a cooling device structured in this way is only suitable for use with a specific combination of components. If, for example, one component is exchanged for another component with changed (height) dimensions, for example in the scope of a revision or during maintenance work, the cooling device also has to be adapted accordingly. The compatibility of the electronic device is thus restricted depending on the individual components to the use with a specific structured cooling device.

A high level of production expenditure is thus caused and only limited usability is provided.

The invention is based on an object of providing an electronic device and a system which enable improved usability with low production expenditure.

This object is achieved by the subjects of the present disclosure. Advantageous embodiments are also specified in the following description, each of which can represent aspects of the invention as such or in (sub-)combination.

According to one aspect, an electronic device is provided, which comprises at least one printed circuit board and at least one electrical or electronic component. The printed circuit board has an assembly side and an opposite soldering side and comprises at least one opening, which corresponds to the at least one component and is continuous in the thickness direction of the printed circuit board. The at least one component adjoins the opening or protrudes therein, so that the component is exposed from the soldering side and can be cooled by a cooling device facing toward the soldering side.

The electrical or electronic component is in particular a wired component, thus one that is provided for THT soldered bonds and/or SMT soldered bonds or the like for the purpose of mounting on printed circuit boards.

Due to the opening in the printed circuit board, the component can be positioned in the opening such that at least one component surface of the component provided for the coupling with a cooling device is arranged in a defined location relative to the printed circuit board. Nonetheless, the printed circuit board can be assembled with respect to the component from the assembly side, so that assembly devices do not have to be complexly adapted. The component surface of the component is arranged due to the opening relative to the printed circuit board such that it is exposed on the soldering side of the printed circuit board. For cooling the component, the cooling device therefore no longer has to be arranged on the assembly side, but rather can advantageously be provided on the soldering side. The structuring of the cooling device can thus be simplified, since it does not have to be adapted to the height profile of the components on the assembly side of the printed circuit board. Moreover, a replacement of one component by another component having a differing height dimension can be enabled, such that the replacement component is exposed in the same manner on the soldering side of the printed circuit board. The replacement component having a differing height dimension can thus be cooled in the same manner by the same cooling device. Only an adaptation of the fixing of the replacement component relative to the printed circuit board can be necessary.

In one embodiment, the printed circuit board can have multiple electrical or electronic components and respective assigned openings. At least one component is arranged in each of the openings such that it is also exposed from the soldering side and can be cooled from the soldering side by the cooling device. Multiple and in particular all components which have to be cooled by a cooling device can thus be cooled from the soldering side if corresponding openings are provided in the printed circuit board. The fact that these components (and other components not to be cooled) have a varying height profile on the assembly side of the printed circuit board can then advantageously remain insignificant.

Preferably, at least some of the components arranged in the respective openings can have flush component surfaces pointing toward the soldering side, which face toward the cooling device. Preferably, all components which are assigned to an opening have flush component surfaces pointing toward the soldering side. A cooling plane of the components is therefore provided by the flush component surfaces, which is arranged parallel to the surface of the soldering side of the printed circuit board. This cooling plane can then be coupled with a cooling device, which does not have to have complex structuring. Rather, the cooling device can have a planar cooling surface for coupling with the flush component surfaces of the components. The production expenditure is thus reduced. Moreover, the compatibility of the electronic device is improved, since components which have different height dimensions can nonetheless be arranged in the openings such that they have component surfaces flush with other components.

The at least one component can only be coupled by soldered bonds with the at least one printed circuit board. In particular, the soldered bonds can point in a conventional manner toward the assembly side. Alternatively, the soldered bonds can point toward the soldering side. Since the component is fixed in the opening in the plane of the printed circuit board, the mechanical connection to the printed circuit board then takes place solely via the soldering process. No further mechanical mounting components are thus required. The assembly devices then do not need to be adapted.

According to one embodiment, the at least one component can be coupled with at least one conductor track of the at least one printed circuit board by wave soldering. Wave soldering is a particularly efficient connection technology, because of which the mounting expenditure and the production expenditure and the costs are reduced.

At least one component arranged in an opening can comprise a coil or a semiconductor component. The present mounting concept can be applied in general to a large number of different component types. These can advantageously all have heat conduction paths which are oriented in parallel.

The coil can be configured to act as a current-compensated choke. In particular, the coil can act as an EMC filter choke. Such coils typically have to be cooled. The opening of the printed circuit board enables an implementation of the cooling from the direction of the soldering side.

According to a further aspect, a system having an electronic device according to the invention and a cooling device is provided. The cooling device has at least one cooling surface which is arranged parallel to the soldering side of the printed circuit board. In particular, the cooling surface of the cooling device can be planar. Structuring of the cooling surface of the cooling device can therefore be avoided. The production expenditure is therefore reduced. Nonetheless, the cooling device is configured for use with flush component surfaces of components to be cooled.

According to one embodiment, the cooling surface of the cooling device is in heat-conductive contact with multiple components of the electronic device, which are arranged in respective openings of the printed circuit board. The contact (thermal contact) can be direct (immediate) in each case or can be provided with the aid of a solid-state heat bridge (indirect). The solid-state heat bridge can be configured to compensate for minor irregularities between component surfaces of the components to be cooled and the cooling surface of the cooling device. The cooling device is thus configured for coupling with various components which are assigned to respective openings of the printed circuit board. Even varying height dimensions of the components do not require structuring of the cooling surface of the cooling device.

Optionally, a heat conduction pad and/or a heat conduction medium can be arranged between the cooling surface of the cooling device and at least one component surface of at least one component arranged in an opening of the printed circuit board. Even minor deviations with respect to the parallelism of the component surface of the component to be cooled and the cooling surface of the cooling device can thus be compensated for cost-effectively in that a good thermal heat conduction path is nonetheless provided.

The invention and further advantageous embodiments and refinements thereof will be described and explained in more detail hereinafter on the basis of the examples shown in the drawings.

### BRIEF DESCRIPTION OF THE DRAWINGS

FIG. 1 shows a simplified schematic representation of a part of an electronic device in the direction of the assembly side of a printed circuit board,

FIG. 2 shows a simplified schematic representation of a part of an electronic device in the direction of the soldering side of the printed circuit board, and

FIG. 3 shows a simplified schematic side view of a system comprising an electronic device and a cooling device.

### DETAILED DESCRIPTION OF THE DRAWINGS

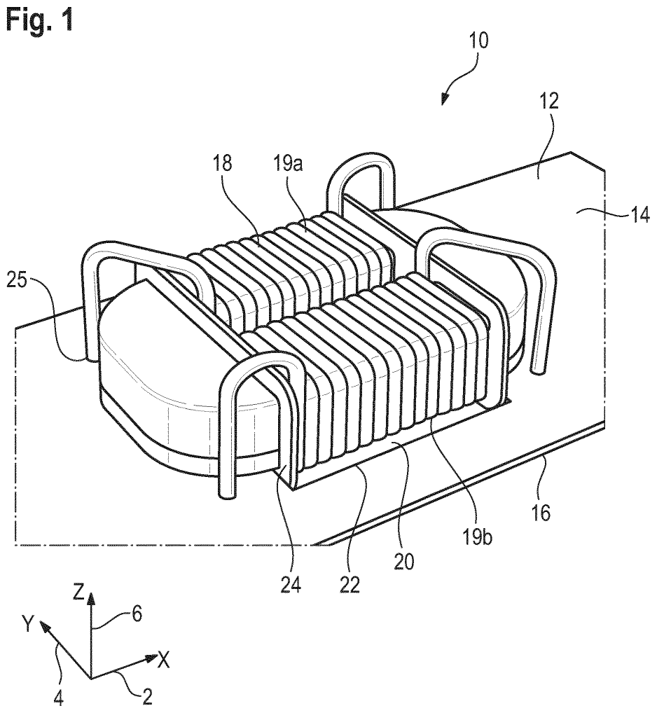

FIG. 1 shows a simplified schematic representation of a part of an electronic device 10 in the direction of the assembly side 14 of the printed circuit board 12. The electronic device 10 comprises the printed circuit board 12.

The printed circuit board 12 has an assembly side 14 and an opposite soldering side 16. A component 18 is arranged on the printed circuit board 12. For this purpose, the printed circuit board 12 comprises an opening 20, which is formed continuously through the printed circuit board 12 in the thickness direction of the printed circuit board 12 along the z direction 6. The component 18 and the opening 20 are assigned to one another. The component 18 is arranged in the opening 20 so that one component section 19a of the component 18 is arranged on the assembly side 14 and another component section 19b of the component 18 is arranged on the soldering side 16, wherein the component is predominantly located on the assembly side 14.

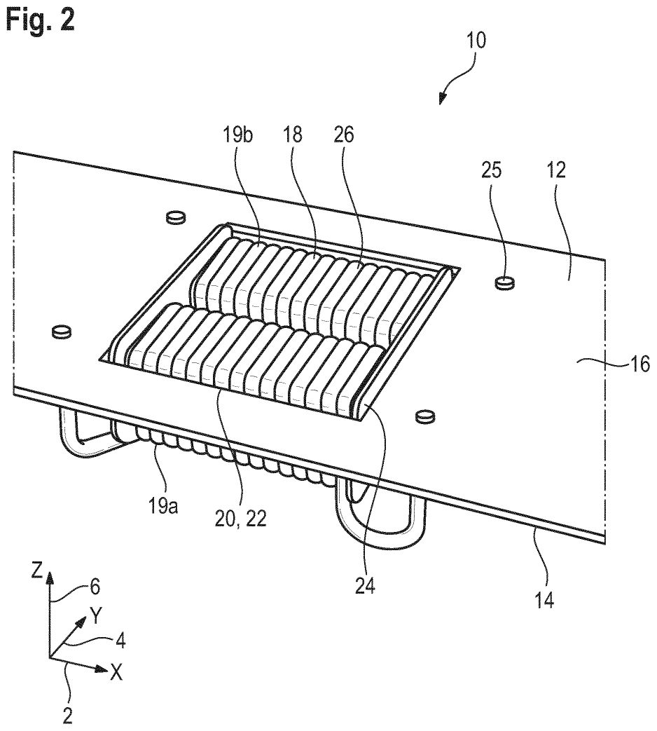

FIG. 2 shows a simplified schematic representation of a part of an electronic device 10 in the direction of the soldering side 16 of the printed circuit board 12.

The opening 20 has a cross-sectional contour 22, which corresponds to the component contour 24. Along the x direction 2 and the y direction 4, the component 18 is therefore fixed in the opening 20 by the corresponding dimensions. Small distances between the component contour 24 and the cross-sectional contour 22 can be provided for mounting purposes. The component 18 is solely coupled with the printed circuit board 12 by soldered bonds 25. For this purpose, supply lines of the component 18 are coupled by the soldered bonds 25 with conductor tracks of the printed circuit board 12.

The soldered bonds 25 can preferably be provided by wave soldering. Since the component is fixed in the x-y direction 2, 4 in the opening 20, the positioning of the component 18 in the z direction 6 is defined by the soldered bonds 25. This means that the soldered bonds 25 are embodied such that the desired component sections 19a, 19b are provided on both sides of the assembly side 14 and the soldering side 16. Although one component section 19b of the component 18 is arranged on the soldering side 16 of the printed circuit board 12, the component 18 can be arranged on the printed circuit board 12 in a conventional manner starting from the assembly side 14.

The component section 19b of the component 18, which is arranged on the soldering side 16 of the printed circuit board 12, has a component surface 26 pointing toward the soldering side 16, which is provided in general for coupling with a cooling device. This means that the heat conduction path in the z direction 6 is provided in the direction of the soldering side 16. The component 18 is thus not cooled from the direction of the assembly side 14, as is typical in the prior art.

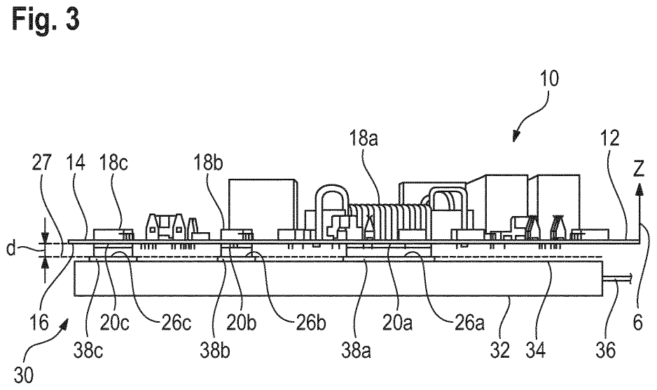

FIG. 3 shows a simplified schematic side view of a system 30 comprising an electronic device 10 and a cooling device 32.

Multiple electrical or electronic components are arranged on the printed circuit board 12 of the electronic device 10. Some of the components do not have to be cooled. However, cooling is provided for the components 18a, 18b, 18c. For example, the component 18a is a current-compensated coil, in particular an EMC filter choke.

The component 18b is a semiconductor component. Each of the components 18a, 18b, 18c is respectively assigned to one opening 20a, 20b, 20c of the printed circuit board 12. As described above, the components 18a, 18b, 18c are arranged in the respective opening 20a, 20b, 20c such that they have component surfaces 26a, 26b, 26c pointing toward the soldering side 16 of the printed circuit board 12. The components 18a, 18b, 18c are coupled in the z direction 6 with the printed circuit board 12 by soldered bonds 25 such that the component surfaces 26a, 26b, 26c are flush with one another and form a cooling plane 27. The cooling plane 27 is arranged parallel to the soldering side 16 of the printed circuit board 12 and has a distance d in relation thereto in the z direction 6. Although the components 18a, 18b, 18c have differing height dimensions in the z direction 6, a uniform cooling plane 27 is thus nonetheless provided in the direction of the soldering side 16. The height deviations between the components 18a, 18b, 18c on the assembly side 14 of the printed circuit board 12 can thus be neglected with regard to the cooling. In the x-y plane 2, 4, the components 18a, 18b, 18c are fixed in the respective openings 20a, 20b, 20c by cross-sectional contours 22 and component contours 24 corresponding to one another.

The cooling device 32 of the system 30 comprises a cooling surface 34, which is arranged parallel to the soldering side 16 of the printed circuit board 12. The cooling surface 34 is provided for coupling with the component surfaces 26a, 26b, 26c. The cooling surface 34 does not need to be structured along the z direction 6, since the cooling plane 27 is flat. The cooling surface 34 can therefore also be planar. The cooling device 32 can therefore be produced with low production expenditure. The cooling device 32 is coupled by a coolant fitting 36 to a coolant circuit in order to circulate a cooling medium, by which heat removal is enabled. Of course, the cooling device can also be passive and can have, for example, cooling ribs on a surface opposite to the cooling surface 34.

In the present case, heat conduction pads 38a, 38b, 38c, which can compensate for minor irregularities, are arranged between the component surfaces 26a, 26b, 26c and the cooling surface 34 of the cooling device 32. The heat conduction pads 38a, 38b, 38c in this respect represent solid-state heat bridges. However, these are optional. The heat conduction path can also be established by direct (immediate) heat-conductive contact between the component surfaces 26a, 26b, 26c and the cooling surface 34.

1-10. (canceled)

11. An electronic device comprising:
at least one printed circuit board; and
at least one electrical or electronic component,
wherein the printed circuit board comprises:
an assembly side and an opposite soldering side; and
at least one opening, which corresponds to the at least one component and is continuous in a thickness direction of the printed circuit board,
wherein the at least one component adjoins the opening or protrudes therein, so that the component is exposed from the soldering side and can be cooled by a cooling device facing toward the soldering side.

12. The electronic device according to claim 11,
wherein the printed circuit board comprises a plurality of electrical or electronic components and respective assigned openings, wherein at least one electrical or electronic component is arranged in each of the openings such that it is exposed from the soldering side and can also be cooled by the cooling device from the soldering side.

13. The electronic device according to claim 12,
wherein the plurality of components arranged in the respective openings have flush component surfaces pointing toward the soldering side, which face toward the cooling device.

14. The electronic device according to claim 11,
wherein the at least one component is solely coupled with the at least one printed circuit board by means of soldered bonds.

15. The electronic device according to claim 14,
wherein the at least one component is coupled with at least one conductor track of the at least one printed circuit board via wave soldering.

16. The electronic device according to claim 11,
wherein at least one component arranged in the opening comprises a coil or a semiconductor component.

17. The electronic device according to claim 16,
wherein the coil is configured to act as a current-compensated choke as an EMC filter choke.

18. A system comprising:
the electronic device according to claim 11; and
the cooling device, wherein the cooling device has at least one planar cooling surface arranged parallel to the soldering side of the printed circuit board.

19. The system according to claim 18,
wherein the cooling surface of the cooling device is in heat-conductive contact with multiple components of the electronic device that are arranged in respective openings of the printed circuit board.

20. The system according to claim 18,
wherein a heat conduction pad and/or a heat conduction medium is arranged between the cooling surface and at least one component surface of the at least one component arranged in the opening of the printed circuit board.
